(19) United States
(12) Patent Application Publication
(10) Pub. No.: US 2026/0121621 A1
(43) Pub. Date: Apr. 30, 2026

(54) RING OSCILLATOR

(71) Applicant: STMicroelectronics International N.V., Geneva (CH)

(72) Inventor: Dominique BERGER, Voiron (FR)

(73) Assignee: STMicroelectronics International N.V., Geneva (CH)

(21) Appl. No.: 19/374,040

(22) Filed: Oct. 30, 2025

(30) Foreign Application Priority Data
Oct. 31, 2024 (FR) FR2411946

(51) Int. Cl. H03K 3/03; H03L 7/099

(52) U.S. Cl. CPC H03K 3/0315; H03L 7/0995

(57) ABSTRACT

A ring oscillator generates an output signal having a frequency controlled by a first frequency control current applied to a frequency control terminal. A first transistor of a first conductivity type receives a control voltage on a control terminal and supplies the first frequency control current at a first conduction terminal. A second transistor of a second conductivity type, opposite from the first conductivity type, also receives the control voltage on a control terminal and supplies a second current to a second conduction terminal of the first transistor.

### PRIORITY CLAIM

This application claims the priority benefit of French Application for Patent No. FR2411946, filed on Oct. 31, 2024, the content of which is hereby incorporated by reference in its entirety to the maximum extent allowable by law.

### TECHNICAL FIELD

The present disclosure generally concerns electronic systems and devices and, more particularly, circuits for controlling electronic systems and devices. The present disclosure more specifically relates to a ring oscillator and to its frequency control circuit.

### BACKGROUND

There exist a multitude of circuits which are configured to generate signals and, in particular, configured to generate periodic signals.

Ring oscillators are well-known circuits that generate periodic signals, which are often used to generate clock signals.

It would be desirable to be able to improve, at least partly, certain aspects of known signal generation circuits, and in particular, certain aspects of known circuits for controlling signal generation circuits.

There exists a need for a more precise circuit for controlling the frequency of a signal supplied by a ring oscillator.

There exists a need for a more precise method of controlling the frequency of a signal supplied by a ring oscillator.

There exists a need for a more precise ring oscillator.

There is a need in the art to overcome all or part of the disadvantages of known circuits for controlling the frequency of a ring oscillator.

There is a need in the art to overcome all or part of the disadvantages of ring oscillators.

### SUMMARY

An embodiment provides a circuit and method for adding, to the control current supplied by a control circuit, a current inversely proportional to a voltage for controlling the frequency of the control circuit.

An embodiment provides a circuit configured to control a frequency of an output signal of a ring oscillator comprising: a first transistor of a first type configured to receive a control voltage on its control terminal and supply a first frequency control current at a first conduction terminal; a second transistor of a second type, different from the first type, configured to receive said control voltage on its control terminal and supply a second current at a second conduction terminal of said first transistor.

Another embodiment provides a method of controlling a frequency of an output signal of a ring oscillator using a circuit comprising: a first transistor of a first type configured to receive a control voltage on its control terminal and supply a first frequency control current at a first conduction terminal; a second transistor of a second type, different from the first type, configured to receive said control voltage on its control terminal and to supply a second current at a second conduction terminal of said first transistor.

According to an embodiment, said first and second transistors are MOS transistors.

According to an embodiment: said first transistor is an NMOS-type transistor; and said second transistor is a PMOS-type transistor.

According to an embodiment, said first and second transistors are bipolar transistors.

According to an embodiment: said first transistor is an NPN-type transistor; and said second transistor is a PNP-type transistor.

According to an embodiment, said second transistor is configured to supply said second current via a current mirror.

According to an embodiment, said second conduction terminal of said first transistor is coupled to a resistor.

Another embodiment provides a ring oscillator comprising the circuit previously-described above.

Another embodiment provides an electronic device comprising an oscillator previously-described above.

According to an embodiment, the device is a phase-locked loop.

Another embodiment provides an electronic system comprising a device previously-described above.

According to an embodiment, the system is a controller, a microcontroller, a processor, or a microprocessor.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an embodiment of a ring oscillator and a frequency control circuit;

FIG. 2 shows curves illustrating the operation of the control circuit of FIG. 1;

FIG. 3 shows an electronic device using the embodiment of FIG. 1; and

FIG. 4 shows an electronic system using the embodiment of FIG. 1.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

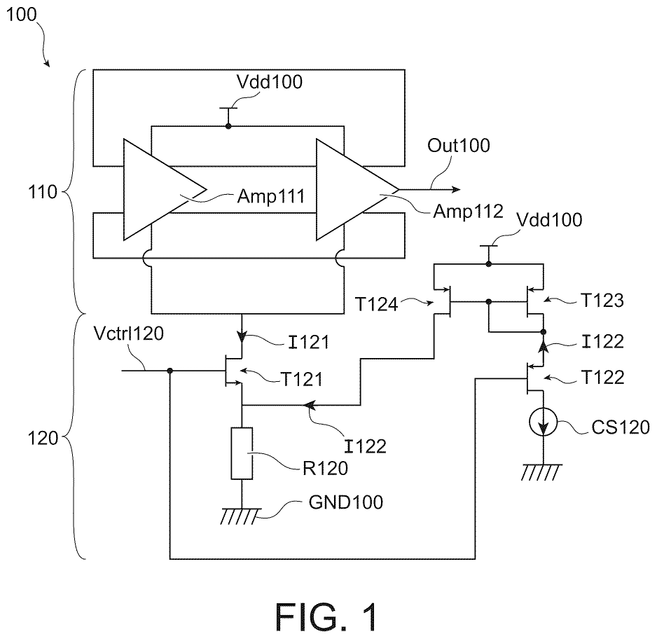

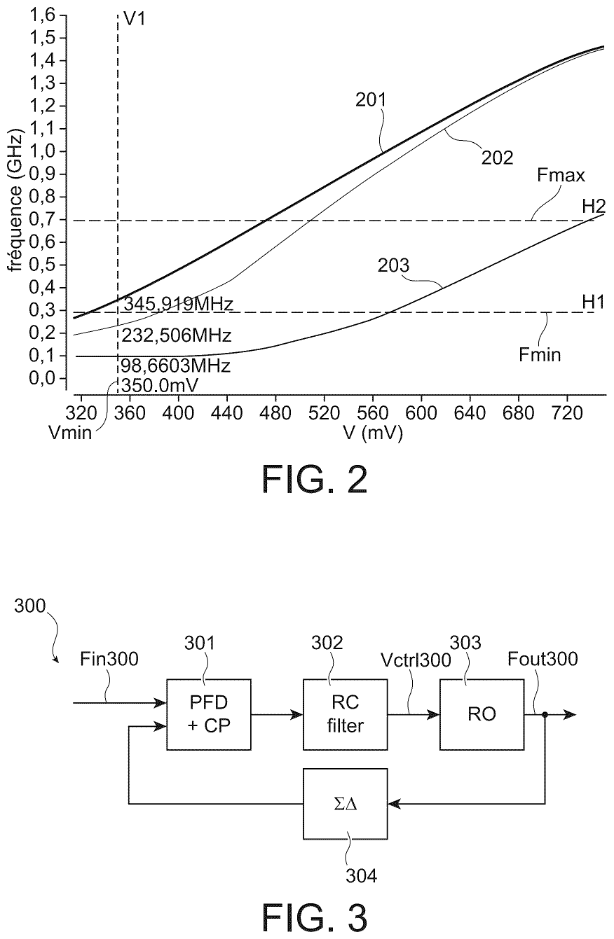

The embodiments described hereafter concern the adjustment of a ring oscillator frequency control. More particularly, these embodiments use the adding of a current inversely proportional to a control voltage on a terminal of a transistor supplying a frequency control current. These embodiments are described in relation with FIGS. 1 and 2.

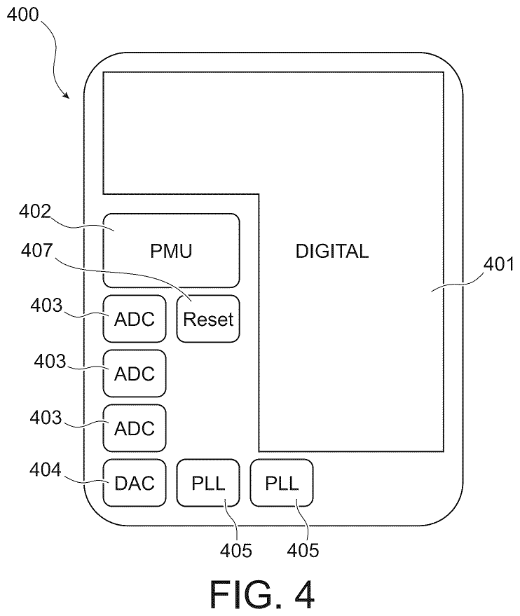

Further, the embodiments described hereafter are particularly adapted to being used in a phase-locked loop (PLL), for example a phase-locked loop used in a microcontroller. These applications are described in further detail in relation with FIGS. 3 and 4.

Further, the embodiments described hereabove are particularly adapted to being used in any type of industrial market where the use of a ring oscillator is required. More particularly, such a ring oscillator may be intended for: the automotive industry, for example in the field of automotive electrification or in the field of advanced driver assistance systems (ADAS); the industrial sector, for example in the field of green energy, in the field of infrastructure electrification, of the Internet of Things (IoT), and of smart homes, where electricity and energy consumption and data exchange are key elements; the personal electronics industry, for example in the field of mobile telephony and of the Internet of Things (IoT), as well as in the field of high speed interfaces; and the industry of communications equipment, computers, and peripherals, for example in the field of infrastructures and data centers, and in the field of low earth orbit (LEO) satellites.

FIG. 1 shows an embodiment of an electronic circuit 100 for generating a periodic signal.

According to an embodiment, circuit 100 is a ring oscillator (RO) accompanied by a circuit for controlling the frequency of its output signal Out100. In other words, circuit 100 comprises: a ring oscillator 110; and a control circuit 120 for controlling the frequency of an output signal Out100 of ring oscillator 110.

According to an embodiment, ring oscillator 110 is configured to supply output signal Out100. This signal Out100 is a periodic signal, for example a signal that can be used as a clock signal. According to an embodiment, the frequency of signal Out100 is set, fixed, modified, or controlled via a control current 1121 supplied by control circuit 120.

According to an example, ring oscillator 110 comprises at least two amplifiers Amp111 and Amp112 having differential inputs and outputs. The outputs of amplifier Amp111 are coupled, preferably connected, to the inputs of amplifier Amp112. The outputs of amplifier Amp112 are coupled, preferably connected, to the inputs of amplifier Amp111. According to an example, amplifiers Amp111 and Amp112 are configured to be powered with a supply voltage Vdd100. According to an example, amplifiers Amp111 and Amp112 are configured to be supplied with control current 1121 on their control terminals. Other ring oscillator structures may be here used and are within the abilities of those skilled in the art. In particular, any ring oscillator capable of receiving a current frequency control signal is compatible with control circuit 120.

According to an embodiment, control circuit 120 comprises a transistor T121 of a first conductivity type (for example, N-type) and a resistor R120. A first conduction terminal of transistor T121 is configured to supply control current 1121, and a second conduction terminal of transistor T121 is coupled, preferably connected, to a first terminal of resistor R120. A second conduction terminal of resistor R120 is coupled, preferably connected, to a node configured to receive a reference voltage GND100, for example ground. A control terminal of transistor T121 is configured to receive a control voltage Vctrl120.

According to an embodiment, control circuit 120 further comprises a current source CS120 and a transistor T122 of a second conductivity type (for example, P-type). A reference terminal of current source CS120 is coupled, preferably connected, to the node receiving reference voltage GND100. An output terminal of current source CS120 is coupled, preferably connected, to a first conduction terminal of transistor T122. A second conduction terminal of transistor T122 is coupled to the junction point of transistor T121 and resistor R120 via transmission means detailed hereafter, and supplies a current 1122. A control terminal of transistor T122 is configured to receive control voltage Vctrl120.

According to an embodiment, transistors T121 and T122 are transistors of the same technology (for example, MOSFET technology) but of different conductivity types. In other words, transistor T121 is of a first type and transistor T122 is of a second type different from the first type. More particularly, transistors T121 and T122 react in a way opposite to control voltage Vctrl120. More particularly still, transistor T121 becomes more and more conductive as a function of a first variation of control voltage Vctrl120, while for this same variation, transistor T122 becomes less and less conductive, and conversely.

According to an embodiment, control circuit 120 further comprises means for transmitting current 1122, for example a transmit circuit using a current mirroring circuit, delivered by transistor T122 to the junction point of transistor T121 and resistor R120. According to an example, this means is a current mirror assembly, or current mirror for mirrored copying (for example, with a mirror ratio of 1:1) of the input current 1122 from transistor T122 to generate the output current 1122 (derived by mirroring from the input current 1122) which is applied to the node connecting transistor T121 and resistor R120. This current mirror circuit comprises two transistors T123 and T124. According to an example, a first conduction terminal of transistor T123 is coupled, preferably connected, to the second conduction terminal of transistor T122 and to the control terminals of transistors T123 and T124. A first conduction terminal of transistor T124 is coupled, preferably connected, to the junction point of transistor T121 and resistor R120. The second conduction terminals of transistors T123 and T124 are coupled, preferably connected, to a power supply voltage Vdd100 terminal.

According to a first embodiment, transistors T121 and T122 as well as, according to an example, transistors T123 and T124 are all metal-oxide-semiconductor field-effect transistors, for example MOSFET technology transistors or MOS transistors. Further, transistor T121 is an N-channel MOS transistor, or N-type MOS transistor, or NMOS transistor. Further, transistor T122 is a P-channel MOS transistor, or P-type MOS transistor, or PMOS transistor. According to an example, transistors T123 and T124 are PMOS-type transistors.

According to a second embodiment, transistors T121 and T122 and, according to an example, transistors T123 and T124, all are transistors in bipolar technology. Further, transistor T121 is an NPN-type transistor, and transistor T122 is a PNP-type transistor. According to an example, transistors T123 and T124 are PNP-type transistors.

According to an embodiment, a method of controlling the frequency of the output signal Out100 of ring oscillator 110 is as follows. A control voltage is applied to control circuit 120, this voltage enables to make transistor T121 conductive and to make transistor T122 non-conductive, or vice versa, and more specifically, to increase the value of the current 1121 supplied by transistor T121 and to decrease the value of the current 1122 supplied by transistor T122, or vice versa.

FIG. 2 is a graph comprising curves illustrating the operation of the circuit 100 described in relation with FIG. 1.

The graph of FIG. 2 more particularly comprises: a curve 201 illustrating a simulation of the variation of the frequency of an output signal of a circuit similar to the circuit 100 of FIG. 1 but comprising no transistor T122, no current source CS120, and no current transmission means, as a function of the value of control voltage Vctrl120, in the case where circuit 100 has a gain of 125 degrees and of a rapid implementation; a curve 202 illustrating the variation of the frequency of the output signal Out100 of the circuit 100 of FIG. 1 as a function of the value of control voltage Vctrl120, in the case where circuit 100 has a gain of 125 degrees and of a rapid implementation; and a curve 203 illustrating the variation of the frequency of the output signal Out100 of the circuit 100 of FIG. 1 as a function of the value of control voltage Vctrl120, in the case where circuit 100 has a gain of −40 degrees and of a slow implementation.

FIG. 2 also shows a maximum frequency Fmax, a minimum frequency Fmin, and a minimum voltage Vmin.

The advantage of adding current 1122, that is, of using transistor 1122, current source CS120, and the transmission means (current mirror), is to enable circuit 100 to be capable of providing an output signal having a frequency between frequencies Fmin and Fmax as soon as control voltage Vctrl120 is higher than voltage Vmin, when the gain of the circuit is adapted for a case of rapid implementation at a high temperature. It should be noted that this result is not achieved when current 1122 is not added.

FIG. 3 schematically shows in the form of blocks an embodiment of an electronic device 300 using the circuit 100 described in relation with FIG. 1.

According to an example, electronic device 300 is a phase-locked loop (PLL). According to a specific example, device 300 is a phase-locked loop configured to receive, as an input, a signal at a first frequency Fin300 and to supply, as an output, a signal at a second frequency Fout300 which is a multiple of the first frequency Fin300.

For this purpose, device 300 may comprise: an input circuit 301 (PFD+CP); a filtering circuit 302 (RC filter); a ring oscillator circuit 303 (RO) of the type of the circuit 100 described in relation with FIG. 1; and a circuit 304.

Circuit 301 is configured to receive frequency input signal Fin300. According to an example, circuit 301 comprises a phase-frequency detector (PFD), and a charge pump (CP).

Circuit 302 (RC filter) is configured to receive an output signal from circuit 301, and to output a control voltage Vctrl300 towards circuit 303. According to an example, circuit 302 is an RC filtering circuit, that is, of resistor-capacitor type.

Circuit 303 (RO) is a ring oscillator of the type of the circuit 100 described in relation with FIG. 1. Circuit 303 is configured to receive control voltage Vctrl300, corresponding to voltage Vctrl120 of FIG. 1) from circuit 302 and to supplying frequency output signal Fout300.

Circuit 304 is a feedback circuit configured to receive frequency output signal Fout300 and to supply it as an input to circuit 301.

Other applications of the circuit 100 described in relation with FIG. 1 are within the abilities of those skilled in the art.

FIG. 4 shows, schematically and in the form of blocks, an embodiment of an electronic system 400 using the circuit 300 described in relation with FIG. 3.

According to an example, system 400 is a complex electronic system, such as a controller, a microcontroller, a processor, or a microprocessor. According to a specific example, system 400 is a microcontroller.

According to an example, system 400 comprises: one or a plurality of digital circuits 401 (DIGITAL); at least one power management unit 402 (PMU); one or a plurality of analog-to-digital conversion circuits 403 (ADC); one or a plurality of digital-to-analog conversion circuits 404 (DAC); one or a plurality of phase-locked loops 405 (PLL); and at least one reset circuit 407 (Reset).

Other applications of the device 300 described in relation with FIG. 3 are within the abilities of those skilled in the art.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A circuit for controlling a frequency of an output signal of a ring oscillator that includes a frequency control terminal, comprising:
a first transistor of a first conductivity type configured to receive a control voltage on a control terminal, the first transistor including at a first conduction terminal of the first transistor configured to supply a first frequency control current to the frequency control terminal;
a second transistor of a second conductivity type, opposite the first conductivity type, configured to receive said control voltage on a control terminal and generate a second current; and
a transmit circuit configured to apply a third current derived from the second current to a second conduction terminal of said first transistor.

2. The circuit according to claim 1, wherein the transmit circuit comprises a current mirror having an input configured to receive the second current and an output configured to supply the third current to the second conduction terminal of said first transistor, wherein the third current is a mirrored copy of the second current.

3. The circuit according to claim 1, wherein said first and second transistors are MOS transistors.

4. The circuit according to claim 3, wherein:
said first transistor is an NMOS-type transistor; and
said second transistor is a PMOS-type transistor.

5. The circuit according to claim 1, wherein said first and second transistors are bipolar transistors.

6. The circuit according to claim 5, wherein:
said first transistor is an NPN-type transistor; and
said second transistor is a PNP-type transistor.

7. The circuit according to claim 1, further comprising a resistor connected between the second conduction terminal of said first transistor and a reference voltage node.

8. The circuit according to claim 1, further comprising a current source coupled in series with the second transistor.

9. An oscillation circuit, comprising:
a ring oscillator; and
the circuit for controlling according to claim 1.

10. An electronic device, comprising the oscillation circuit according to claim 9.

11. The device according to claim 10, being a phase-locked loop.

12. An electronic system, comprising the electronic device according to claim 10.

13. The system according to claim 12, being one of a controller, a microcontroller, a processor, or a microprocessor.

14. A method of controlling a frequency of an output signal of a ring oscillator, comprising:
supplying a first frequency control current generated at a first conduction terminal of a first transistor of a first conductivity type to a frequency control terminal of the ring oscillator;
supplying a second current generated at a first conduction terminal of a second transistor of a second conductivity type opposite the first conductivity type;
applying a third current derived from the second current to a second conduction terminal of the first transistor; and
applying a control voltage on a control terminal of the first transistor and on a control terminal of the second transistor.

15. The method according to claim 14, wherein applying the third current derived from the second current comprises mirroring the second current to generate the third current.

16. The method according to claim 14, further comprising resistively coupling the second conduction terminal of the first transistor to a reference voltage node.

17. The method according to claim 14, wherein:
said first transistor is an NMOS-type transistor; and
said second transistor is a PMOS-type transistor.

18. The method according to claim 14, wherein:
said first transistor is an NPN-type transistor; and
said second transistor is a PNP-type transistor.
